(19) United States
(12) Patent Application Publication
(10) Pub. No.: US 2026/0090312 A1
(43) Pub. Date: Mar. 26, 2026

(54) SUBSTRATE PROCESSING APPARATUS AND SUBSTRATE PROCESSING METHOD

(71) Applicant: SEMES CO., LTD., Cheonan-si (KR)

(72) Inventors: Hyung Seok KANG, Suwon-si (KR); Joon Ho WON, Suwon-si (KR); Anton KORIAKIN, Suwon-si (KR); Pil Kyun HEO, Yongin-si (KR)

(73) Assignee: SEMES CO., LTD., Cheonan-si (KR)

(21) Appl. No.: 19/340,317

(22) Filed: Sep. 25, 2025

(30) Foreign Application Priority Data
Sep. 26, 2024 (KR) 10-2024-0130394

(51) Int. Cl. H01L 21/67; H01L 21/02

(52) U.S. Cl. CPC H10P 72/0406; H10P 70/80

(57) ABSTRACT

Provided is a method of processing a substrate, the method including: a pressure increasing operation of increasing a pressure of a treatment space to a first set pressure after the substrate is loaded into the treatment space; after the pressure increasing operation, a treating operation of processing the substrate; and after the treating operation, a pressure reducing operation of reducing a pressure of the treatment space, in which the pressure increasing operation includes increasing a pressure of the treatment space by supplying only a supercritical fluid between the supercritical fluid and the organic solvent to the treatment space, and the treating operation includes supplying a mixed fluid obtained by dissolving the organic solvent in the supercritical fluid to the treatment space.

### CROSS-REFERENCE TO RELATED APPLICATION

This application claims priority to and the benefit of Korean Patent Application No. 10-2024-0130394 filed in the Korean Intellectual Property Office on Sep. 26, 2024, the entire contents of which are incorporated herein by reference.

### TECHNICAL FIELD

The present invention relates to an apparatus and method of processing a substrate, and more specifically, to an apparatus and method of processing a substrate with a supercritical fluid and an organic solvent by supplying the supercritical fluid and the organic solvent to the substrate.

### BACKGROUND ART

In order to manufacture a semiconductor device, various processes, such as cleaning, deposition, photography, etching, and ion implantation, are performed. Among the processes, the photography process includes an application process of forming a film by applying a photosensitive liquid, such as a photoresist, on a surface of the substrate, an exposure process that transfers a circuit pattern to the film formed on the substrate, and a developing process that selectively removes the film formed on the substrate in a region on which the exposure process has been performed or a region opposite to the region.

In general, an apparatus for performing a developing process removes a liquid film formed on the substrate by supplying a developer from a nozzle to a rotating substrate. However, since the developer is supplied to the substrate in a liquid state, the density of the developer is high to cause a problem in that in the photoresist film, not only a region in which development should be performed but also a region in which development should not be performed are removed in the exposed region and the non-exposed region.

### SUMMARY OF THE INVENTION

The present invention has been made in an effort to provide a substrate processing apparatus and a substrate processing method capable of improving the processing efficiency of a substrate.

The present invention has also been made in an effort to provide a substrate processing apparatus and a substrate processing method capable of developing only a selected area between an exposed region and an unexposed region during a development process.

The present invention has also been made in an effort to provide a substrate processing apparatus and a substrate processing method capable of continuously supplying a supercritical fluid without a hunting phenomenon.

Effects of the present disclosure are not limited to those described above and effects not stated above will be clearly understood to those skilled in the art from the specification and the accompanying drawings.

An exemplary embodiment of the present disclosure, a method of processing a substrate, the method comprising: a pressure increasing operation of increasing a pressure of a treatment space to a first set pressure after the substrate is loaded into the treatment space; after the pressure increasing operation, a treating operation of processing the substrate; and after the treating operation, a pressure reducing operation of reducing a pressure of the treatment space, wherein the pressure increasing operation includes increasing a pressure of the treatment space by supplying only a supercritical fluid between the supercritical fluid and the organic solvent to the treatment space, and the treating operation may includes supplying a mixed fluid obtained by dissolving the organic solvent in the supercritical fluid to the treatment space.

According to the exemplary embodiment of the present invention, wherein the mixed fluid may be produced by supplying the supercritical fluid and the organic solvent to a reservoir and mixing the supercritical fluid and the organic solvent in the reservoir.

According to the exemplary embodiment of the present invention, wherein a plurality of reservoirs is provided, and the treating operation may includes, supplying the mixed fluid to the treatment space through only a first reservoir among the plurality of reservoirs; and when a pressure of the mixed fluid in a supply pipe connecting the first reservoir to the treatment space is equal to or less than a second set pressure, stopping the supply of the mixed fluid from the first reservoir, and supplying the mixed fluid to the treatment space only through a second reservoir among the plurality of reservoirs.

According to the exemplary embodiment of the present invention, wherein the first reservoir and the second reservoir may supply the mixed fluid having the same concentration or density to the treatment space.

According to the exemplary embodiment of the present invention, wherein a plurality of reservoirs is provided, and some of the plurality of reservoirs may be provided to supply the mixed fluid of different concentrations or densities to the treatment space.

According to the exemplary embodiment of the present invention, wherein the first set pressure may be a process pressure.

According to the exemplary embodiment of the present invention, wherein the first set pressure may be a pressure for maintaining a state in which the organic solvent in the mixed fluid supplied to the treatment space is dissolved in the supercritical fluid.

According to the exemplary embodiment of the present invention, wherein the substrate loaded in in the pressure increasing operation is a substrate on which an exposure process has been performed on a photoresist applied on the substrate, and in the treating operation, the treatment of the substrate may be a treatment that performs a development process on the substrate.

According to the exemplary embodiment of the present invention, wherein the organic solvent may be any one of n-butyl alcohol (nBA) and isopropyl alcohol (IPA).

According to the exemplary embodiment of the present invention, wherein the supercritical fluid may be carbon dioxide.

An exemplary embodiment of the present disclosure, an apparatus for processing a substrate, the apparatus comprising: a process chamber having a treatment space therein; support unit for supporting the substrate within the treatment space; a mixed fluid supply unit for supplying a mixed fluid, in which an organic solvent is dissolved in a supercritical fluid, to the treatment space; a supercritical fluid supply unit for supplying a supercritical fluid to the treatment space; an exhaust unit for exhausting the treatment space; and a controller for controlling the process chamber, the mixed fluid supply unit, and the supercritical fluid supply unit, wherein the supercritical fluid supply unit includes: a reservoir for dissolving the organic solvent in the supercritical fluid to produce and store the mixed fluid; a mixed fluid supply pipe for supplying the mixed fluid in the reservoir to the process chamber; a supercritical fluid supply pipe for supplying the supercritical fluid to the reservoir; and an organic solvent supply pipe for supplying the organic solvent to the reservoir, and the controller may controls the process chamber, the mixed fluid supply unit, and the supercritical fluid supply unit to increase a pressure of the treatment space by supplying only the supercritical fluid between the supercritical fluid and the organic solvent to the treatment space through the supercritical fluid supply unit until a pressure of the treatment space reaches a first set pressure, and supply the mixed fluid to the treatment space through the mixed fluid supply unit to process the substrate when the pressure in the treatment space becomes a first set pressure.

According to the exemplary embodiment of the present invention, wherein the plurality of reservoirs, the plurality of supercritical fluid supply pipes, and the plurality of organic solvent supply pipes are provided, and one supercritical fluid supply pipe and one organic solvent supply pipe may be connected to each of the plurality of reservoirs.

According to the exemplary embodiment of the present invention, wherein each of the reservoirs may produces the mixed fluid of the same concentration or density.

According to the exemplary embodiment of the present invention, wherein some of the plurality of reservoirs may produce the mixed fluids of different concentrations or densities.

According to the exemplary embodiment of the present invention, wherein the controller may controls the mixed fluid supply unit to supply the mixed fluid to the process chamber only through a first reservoir among the plurality of reservoirs, and to stop the supply of the mixed fluid through the first reservoir and supply the mixed fluid to the process chamber only through a second reservoir among the plurality of reservoirs when a pressure of the mixed fluid in the fluid supply pipe is equal to or less than a second set pressure.

According to the exemplary embodiment of the present invention, wherein the organic solvent may be any one of n-butyl alcohol (nBA) and isopropyl alcohol (IPA).

According to the exemplary embodiment of the present invention, wherein the supercritical fluid may be carbon dioxide.

An exemplary embodiment of the present disclosure, a method of processing a substrate, the method comprising: a loading operation of loading a substrate, in which an exposure process has been performed on a photoresist applied on the substrate, into a treatment space; a pressure increasing operation of increasing a pressure of the treatment space to a first set pressure after the loading operation; after the pressure increasing operation, a treating operation of developing the substrate; and after the treating operation, a pressure reducing operation of reducing a pressure of the treatment space, wherein the pressure increasing operation includes increasing a pressure of the treatment space by supplying only the supercritical fluid between the supercritical fluid and the organic solvent to the treatment space, the treating operation includes supplying a mixed fluid obtained by dissolving the organic solvent in the supercritical fluid to the treatment space, the organic solvent is any one of n-butyl alcohol (nBA) and isopropyl alcohol (IPA), and the supercritical fluid may be carbon dioxide.

According to the exemplary embodiment of the present invention, wherein the mixed fluid may be produced by supplying the supercritical fluid and the organic solvent to the reservoir and mixing the supercritical fluid and the organic solvent in the reservoir.

According to the exemplary embodiment of the present invention, wherein the treating operation may includes, supplying the mixed fluid to the treatment space through only a first reservoir among the plurality of reservoirs; and when a pressure of the mixed fluid in a supply pipe connecting the first reservoir to the treatment space is equal to or less than a second set pressure, stopping the supply of the mixed fluid from the first reservoir, and supplying the mixed fluid to the treatment space only through a second reservoir among the plurality of reservoirs.

According to the exemplary embodiment of the present invention, it is possible to improve substrate processing efficiency.

According to the exemplary embodiment of the present invention, it is possible to precisely develop a selected region selected between an exposed region and an unexposed region.

According to the exemplary embodiment of the present invention, it is possible to continuously supply the supercritical fluid without a hunting phenomenon.

According to the exemplary embodiment of the present invention, it is possible to maintain a state in which an organic solvent is dissolved in a supercritical fluid in the treatment space.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a supercritical chamber according to an exemplary embodiment of the present invention.

FIGS. 2 and 3 are flowcharts of a substrate processing method according to an exemplary embodiment of the present invention.

FIG. 4 is a diagram schematically illustrating an operation state of the supercritical chamber in a loading operation of FIG. 3.

FIG. 5 is a diagram schematically illustrating an operation state of the supercritical chamber in a pressure increasing operation of FIG. 3.

FIGS. 6 and 7 are diagrams schematically illustrating the operating state of the supercritical chamber in a treating operation of FIG. 3.

FIG. 8 is a diagram schematically illustrating an operation state of the supercritical chamber in a pressure reducing operation of FIG. 3.

FIG. 9 is a diagram schematically illustrating the operation state of the supercritical chamber in an unloading operation of FIG. 3.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between˜and˜”, “just between˜and˜”, or “adjacent to˜” and “directly adjacent to˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

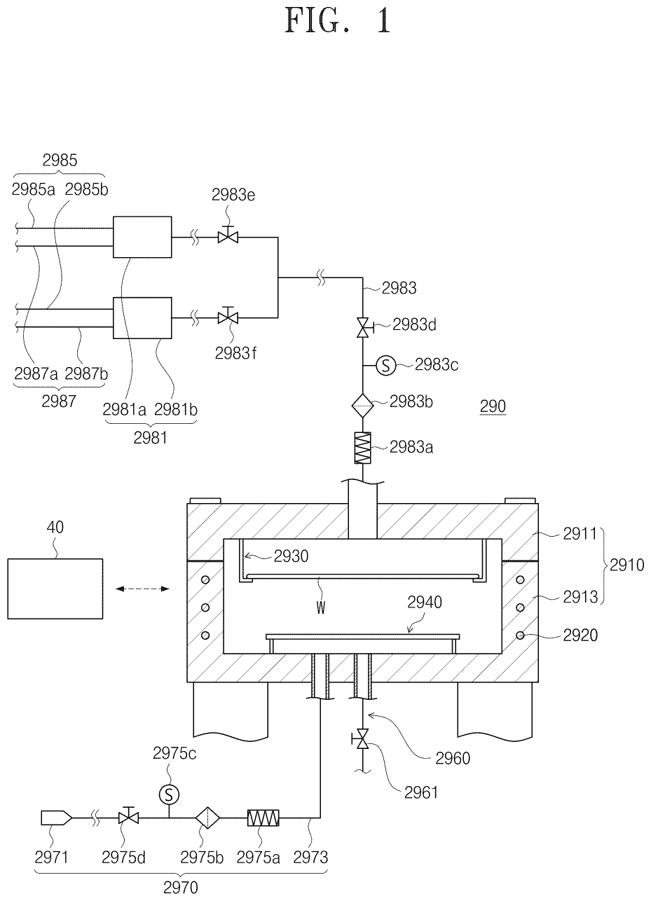

Hereinafter, an exemplary embodiment of the present invention will be described with reference to FIGS. 1 to 9.

FIG. 1 is a diagram schematically illustrating a supercritical chamber according to an exemplary embodiment of the present invention. A supercritical chamber 290 performs a developing process on a substrate W on which the exposure treatment has been completed.

The supercritical chamber 290 includes a housing 2910, a heating member 2920, a support unit 2930, a blocking plate 2940, a driver 2950, an exhaust unit 2960, a supercritical fluid supply unit 2970, and a mixed fluid supply unit 2980.

The housing 2910 provides a treatment space for processing the substrate W. The housing 2910 is made of a material capable of withstanding a high pressure equal to or greater than a critical pressure of the supercritical fluid. The housing 2910 has a first body 2911 and a second body 2913. The first body 2911 and the second body 2913 are combined with each other to provide a treatment space therein. The first body 2911 is located above the second body 2913. One of the first body 2911 and the second body 2913 may be coupled to the driver 2950 and move in the vertical direction. For example, the second body 2913 may be coupled to the driver 2950 and move in the vertical direction by the driver 2950. Accordingly, the treatment space of the housing 2910 may be opened or closed according to the movement of the second body 2913.

The heating member 2920 heats a treatment fluid supplied to the treatment space. The heating member 2920 increases the temperature inside the treatment space. When the heating member 2920 increases the temperature of the treatment space, the treatment fluid supplied to the treatment space is converted into a supercritical state or the treatment fluid is maintained in a supercritical state.

The heating member 2920 may be buried in the housing 2910. The heating member 2920 may be buried in at least one of the first body 2911 and the second body 2913. For example, the heating member 2920 may be provided in each of the first body 2911 and the second body 2913. The heating member 530 may be a heater.

The support unit 2930 supports the substrate W in the treatment space. The support unit 2930 may be coupled to the first body 2911 or the second body 2913 to support the substrate W in the treatment space. For example, the support unit 2930 may be coupled to the first body 2911 to support the substrate W in the treatment space.

The blocking plate 2940 is disposed in the treatment space. The blocking plate 2940 may prevent the treatment fluid from being directly discharged toward the substrate W, thereby preventing the substrate W from being damaged.

The blocking plate 2940 may be disposed to be spaced apart from a bottom surface of the housing 2910 by a predetermined distance. For example, the blocking plate 2940 may be supported by a support so as to be spaced apart from the bottom surface of the housing 2910 in an upward direction. The support may be provided in a rod shape. A plurality of supports may be provided. A plurality of supports is provided to be spaced apart from each other by a predetermined distance.

The exhaust unit 2960 exhausts a fluid remaining in the treatment space to the outside of the supercritical chamber 290. An opening/closing valve 2961 opening and closing an internal flow path is installed in the exhaust unit 2960. According to an example, the exhaust unit 2960 may be connected to the center of the second body 2913. A pressure reducing valve (not illustrated) may be installed in the exhaust unit 2960.

The supercritical fluid supply unit 2970 supplies the supercritical fluid to the treatment space. According to an example, the supercritical fluid may be carbon dioxide. The supercritical fluid supply unit 2970 includes components installed in a supercritical fluid supply source 2971, a supercritical fluid supply pipe 2973, and a supercritical fluid supply pipe 2973. The components may be a heater 2975a, a filter 2975b, a sensor 2975c, a valve 2975d, and the like.

The supercritical fluid supply source 2971 stores and supplies the supercritical fluid. The supercritical fluid supply source 2971 may be a reservoir. The fluid stored in the supercritical fluid supply source 2971 is supplied to the treatment space through the supercritical fluid supply pipe 2973.

The supercritical supply pipe 2973 may increase a pressure of the treatment space by supplying the supercritical fluid to the treatment space. The supercritical supply pipe 2973 is connected to the housing 2910 to supply the supercritical fluid to the treatment space. According to an example, the supercritical supply pipe 2973 may be connected to the second body 2913 to supply the supercritical fluid from a lower portion of the supercritical chamber 290. For example, the supercritical supply pipe 2973 may be connected to a point eccentric from the center of the second body 2913. Accordingly, the blocking plate 2940 may prevent the supercritical fluid from being directly discharged to the substrate W during the pressure increasing process, thereby preventing the substrate W from being damaged. Optionally, the supercritical supply pipe 2973 may be connected to the first body 2911 and may also be connected to the first body 2911 and the second body 2913.

The heater 2975a heats the pipe to adjust the temperature of the treatment fluid flowing through the pipe.

The filter 2975b filters the supercritical fluid provided from the supercritical fluid supply source 2971 to the treatment space. For example, the filter 2975b may filter impurities that may be included in the treatment fluid transferred to the treatment space.

The sensor 2975c may be a pressure sensor or a temperature sensor. The sensor 2975c may measure the temperature or pressure of the treatment space and/or the pipe.

The valve 2975d may be an on/off valve. A flow rate control valve may be optionally further installed. Opening and closing of the valve 2975d determines whether to supply the treatment fluid supplied to the treatment space.

The mixed fluid supply unit 2980 supplies the mixed fluid to the treatment space. The mixed fluid supply unit 2980 includes a reservoir 2981, a mixed fluid supply pipe 2983, a supercritical fluid supply pipe 2985, and an organic solvent supply pipe 2987.

The reservoir 2981 dissolves an organic solvent in the supercritical fluid to produce a mixed fluid and stores the produced mixed fluid. According to an example, the supercritical fluid may be carbon dioxide. According to an example, the organic solvent may be a treatment medium capable of developing a substrate. For example, the organic solvent may be either n-butyl alcohol (nBA) or isopropyl alcohol (IPA).

According to the exemplary embodiment of the present invention, a treatment medium capable of developing the substrate W is supplied to the substrate W in a state of being dissolved in a supercritical fluid, not in a liquid state. Since the mixed fluid has a lower density than the liquid, the reaction rate is slow, so that only a region selected from an exposed region and an unexposed region may be precisely developed.

The mixed fluid supply pipe 2983 may supply the mixed fluid remaining in the reservoir 2981 to the treatment space. According to an example, the mixed fluid supply pipe 2983 may be connected to the first body 2911. For example, the mixed fluid supply pipe 2983 may be connected to the center of the first body 2911. Components may be installed in the mixed fluid supply pipe 2983. The components may be a heater 2983a, a filter 2983b, a sensor 2983c, a valve 2983d, and the like. Since the components have the same or similar functions as those installed in the above-described supercritical fluid supply pipe 2973, redundant contents are omitted.

The supercritical fluid supply pipe 2985 receives a supercritical fluid from the supercritical fluid supply source (not illustrated) and makes the supercritical fluid flow to the reservoir 2981.

The organic solvent supply pipe 2987 receives an organic solvent from an organic solvent supply source (not illustrated) and makes the reservoir 2981 flow to the reservoir 2981.

A plurality of reservoirs 2981 may be provided. The supercritical fluid supply pipe 2985 and the organic solvent supply pipe 2987 may be provided to correspond to the number of reservoirs 2981 to supply supercritical fluid and the organic solvent to the reservoirs 2981, respectively. Hereinafter, a case where two reservoirs 2981a and 2981b, supercritical fluid supply pipes 2985a and 2985b, and organic solvent supply pipes 2987a and 2987b, respectively, are provided will be described as an example.

The mixed fluid supply pipe 2983 may be branched and connected to the reservoirs 2981a and 2981b, respectively. Opening and closing valves 2983e and 2983f may be installed on the branched pipes, respectively.

According to an example, the reservoirs 2981a and 2981b may produce mixed fluids having the same concentration or density. When the mixed fluid is supplied to the treatment space through one reservoir 2981, the supercritical fluid and the organic solvent need to be supplied through the supercritical fluid supply pipe 2985 and the organic solvent supply pipe 2987 to continuously supply the mixed fluid to the treatment space. When the supercritical fluid and the organic solvent are received while the mixed fluid is supplied to the outside, a pressure hunting phenomenon may occur in the reservoir 2981.

According to the exemplary embodiment of the present invention, a plurality of reservoirs 2981a and 2981b for producing a mixed fluid of the same concentration or density is provided, and the mixed fluid is supplied to the treatment space through one of the reservoirs 2981a. When the pressure of the mixed fluid in the mixed fluid supply pipe 2983 falls below a second set pressure, the mixed fluid is supplied to the treatment space through the other reservoir 2981b, and in this case, the supercritical fluid and the organic solvent are supplied to the previously used reservoir 2981a to produce the mixed fluid. As described above, the reservoirs 2981a and 2981b are not supplied with the supercritical fluid and the organic solvent when the mixed fluid is supplied to the treatment space, and thus the pressure hunting phenomenon does not occur in the reservoirs 2981a and 2981b.

Specifically, the controller 40 may control the mixed fluid supply unit to open the opening/closing valve 2983e on the side of the first reservoir 2981a, close the opening/closing valve 2983f on the side of the second reservoir 2981b, supply the mixed fluid into the treatment space only through the first reservoir 2981a, and when the pressure of the mixed fluid in the mixed fluid supply pipe 2983 measured through the sensor 2983c in the mixed fluid supply pipe 2983 is equal to or less than the second set pressure, the controller 40 may control the mixed fluid supply unit to close the opening/closing valve 2983e on the side of the first reservoir 2981a, open the opening/closing valve 2983f on the side of the second reservoir 2981b, and supply the mixed fluid into the treatment space only through the second reservoir 2981b.

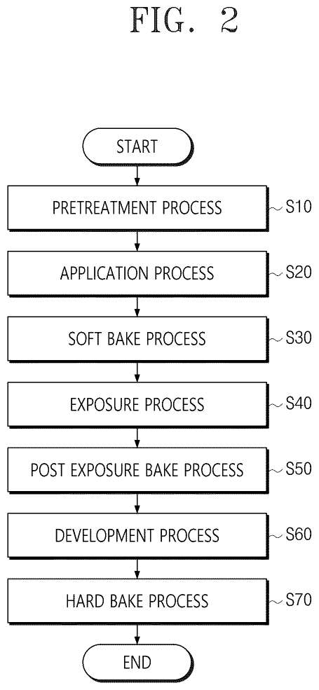

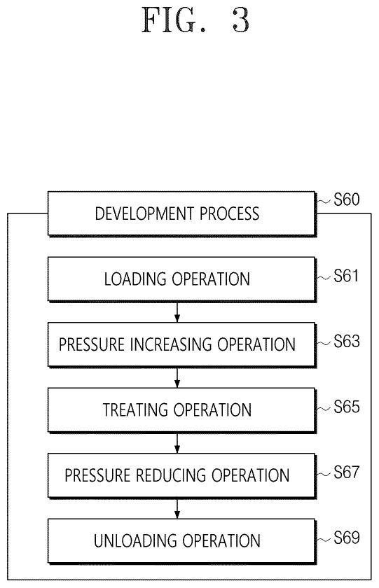

FIGS. 2 and 3 are flowcharts of a substrate processing method according to an exemplary embodiment of the present invention. Referring to FIG. 2, a substrate processing method according to an exemplary embodiment of the present invention includes a pretreatment process S10, an application process S20, a soft bake process S30, an exposure process S40, a Post Exposure Bake (PEB) process S50, a development process S60, and a hard bake process S70.

In the pretreatment process S10, the substrate W may be liquid treated. For example, in the pretreatment process S10, organic matters, ions, metal impurities, or the like attached to the surface of the substrate W may be cleaned. Also, in the pretreatment process S10, hexamethyldisilazane (HMDS) may be supplied onto the substrate W in order to hydrophobize the surface of the substrate W. Accordingly, the substrate W may be hydrophobized in the pretreatment process S10, thereby improving adhesion between the substrate W and the photoresist.

After the pretreatment process S10 is completed, the application process S20 is performed.

The application process S20 supplies a photoresist onto the substrate W. In the application process S20, the photoresist supplied onto the substrate W may be a photoresist for Extreme Ultraviolet Rays (EUV). By supplying the photoresist onto the substrate W in the application process S20, a photoresist layer may be formed on the surface of the substrate W.

After the application process S20 is completed, the soft bake process S30 is performed. The soft bake process S30 performs heat treatment on the substrate W. The soft bake process S30 may heat-treat the substrate W having a photoresist layer formed on the surface thereof. The soft bake process S30 may heat the substrate W to remove the organic solvent present in the photoresist layer. The soft bake process S30 may cool the substrate W after heating the substrate W.

After the soft bake process S30 is completed, the exposure process S40 is performed. In the exposure process S40, after disposing a mask formed with a pattern on the substrate W, light is emitted toward the substrate W. The chemical properties of the photoresist layer in the region which is not light-blocked by the mask change by light, and the properties of the photoresist layer in the region which is light-blocked by the mask do not change.

After the exposure process S40 is completed, the PEB process is performed. In the PEB process S50, the substrate W is heated to a constant temperature to complete the reaction of the exposed photoresist layer, and the residual solvent is removed to stabilize the layer.

After the PEB process S50, the development process S60 is performed. The development process S60 is performed in the supercritical chamber 290. In the development process S60, a target photoresist layer is removed by supplying a mixed fluid to the substrate W.

Referring to FIG. 3, the development process S60 includes a loading operation S61, a pressure increasing operation S63, a treating operation S65, a pressure reducing operation S67, and an unloading operation S69.

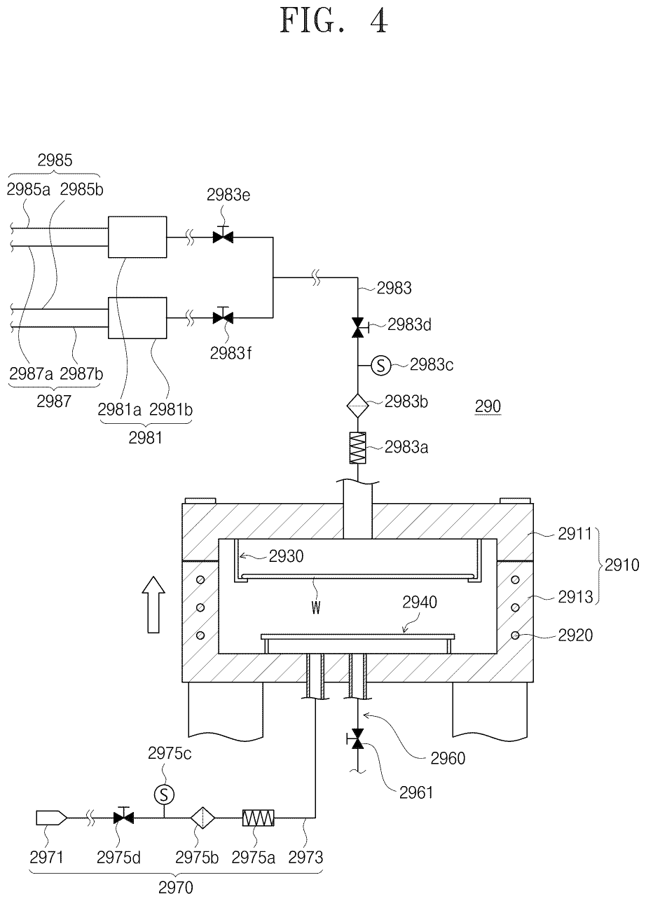

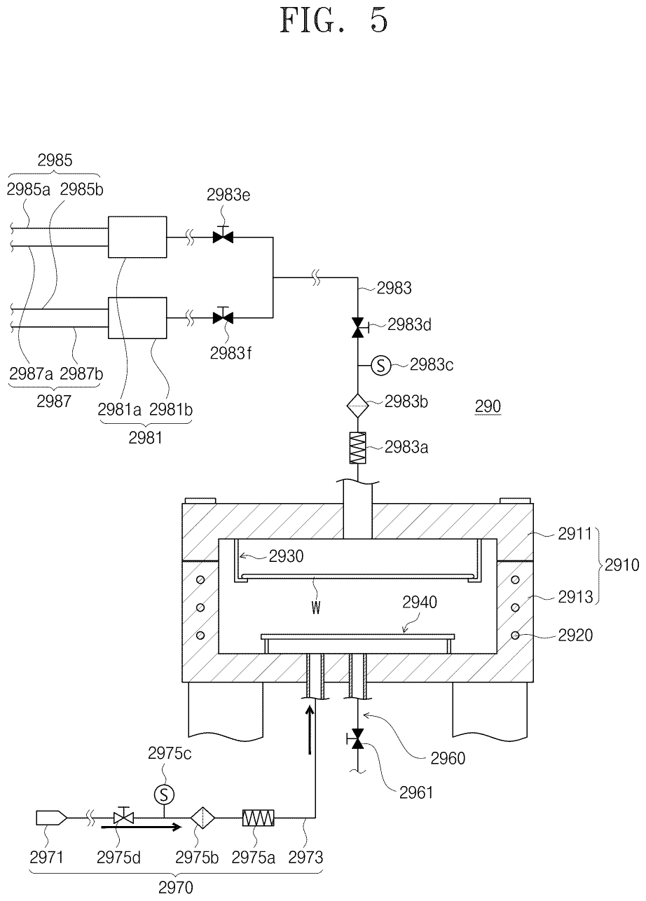

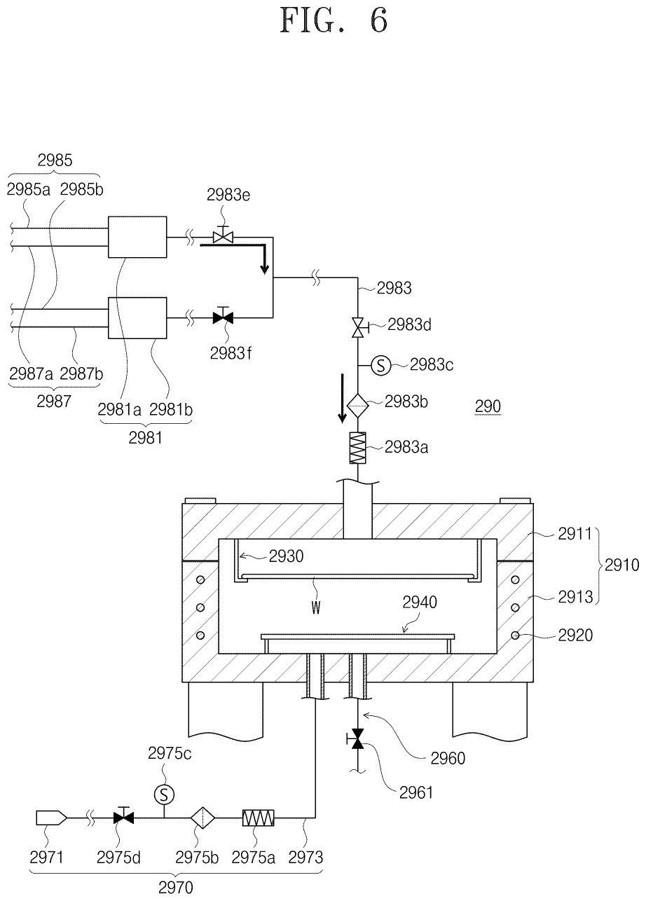

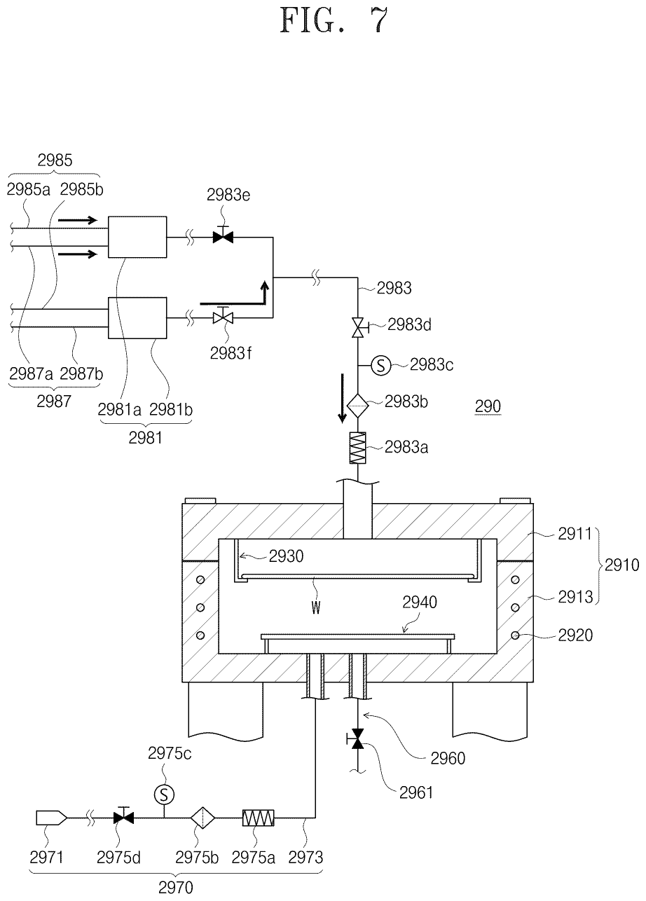

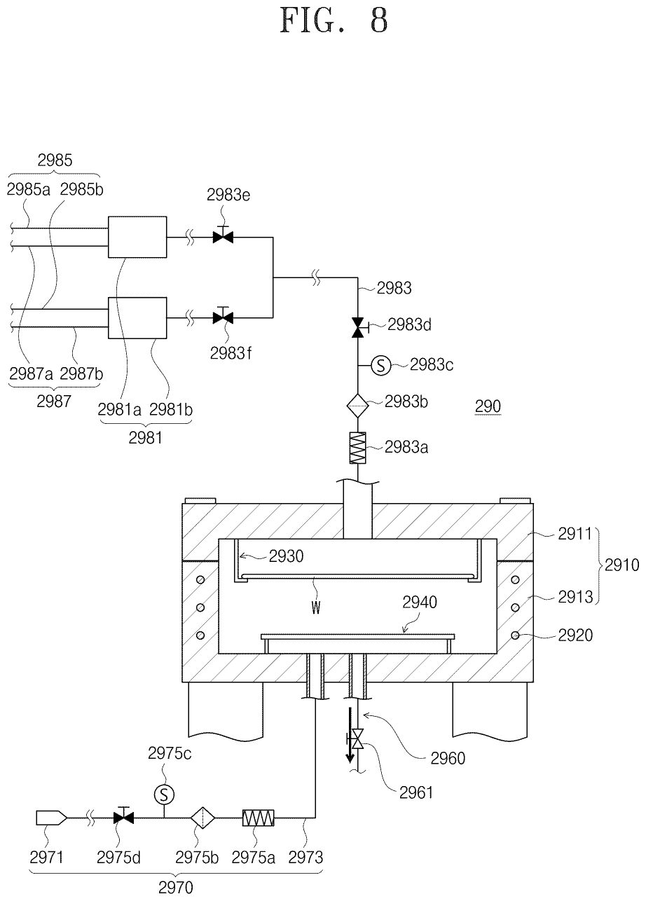

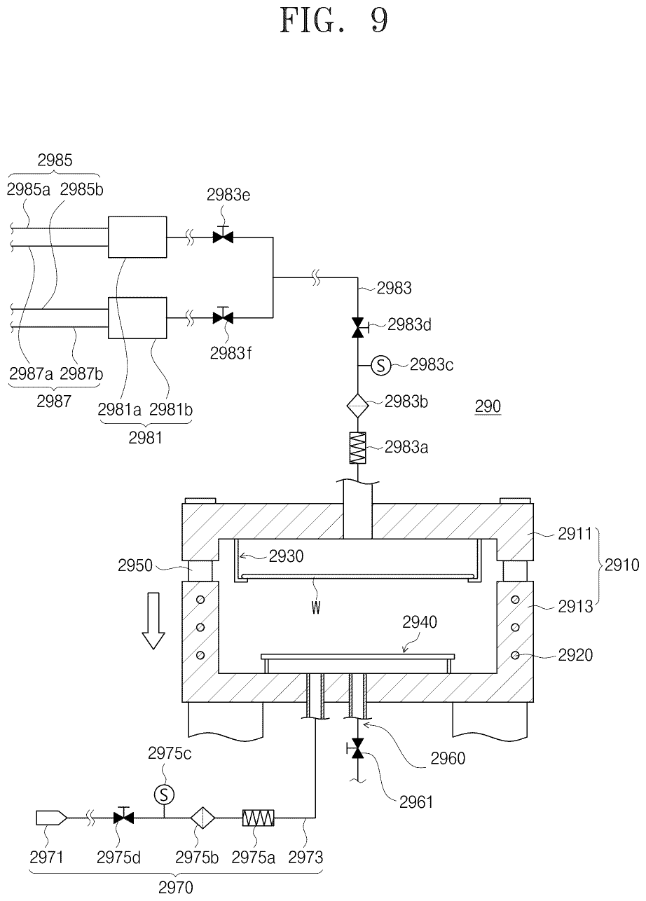

FIG. 4 is a diagram schematically illustrating an operation state of the supercritical chamber in the loading operation of FIG. 3. FIG. 5 is a diagram schematically illustrating an operation state of the supercritical chamber in the pressure increasing operation of FIG. 4. FIGS. 6 and 7 are diagrams schematically illustrating the operating state of the supercritical chamber in the treating operation of FIG. 3. FIG. 8 is a diagram schematically illustrating an operation state of the supercritical chamber in the pressure reducing operation of FIG. 3. FIG. 9 is a diagram schematically illustrating the operation state of the supercritical chamber in the unloading operation of FIG. 3.

In FIG. 4 to FIG. 9, an arrow toward the pipe indicates a flow direction of a supercritical fluid, an organic solvent, or a mixed fluid, and an arrow toward the housing indicates a movement direction of the second body. In addition, the valve filled with the inside is in a closed state that prevents fluid from flowing, and the valve with an empty inside is in an open state that allows fluid to flow.

Referring to FIG. 4, in the loading in operation S61, the substrate W that has completed the application process S20 and the exposure process S40 is loaded into the supercritical chamber 290, and the treatment space is sealed as the second body 2913 rises toward the first body 2911.

After the loading operation S61, the pressure increasing operation S63 starts. Referring to FIG. 5, in the pressure increasing operation S63, the valve 2975d in the supercritical fluid supply pipe 2973 is opened, so that the supercritical fluid is supplied from the supercritical fluid supply source 2971 to the treatment space. At this time, the valves 2983d, 2983e, and 2983f in the mixed fluid supply pipe 2983 are closed.

In the pressure increasing operation S63, the supercritical fluid is supplied to the treatment space until the pressure in the treatment space becomes a first set pressure. The first set pressure may be a pressure for maintaining a state in which the organic solvent is dissolved in the supercritical fluid in the treatment space. For example, the first set pressure may be a process pressure when the development treatment is performed.

When the mixed fluid is supplied to the treatment space while the pressure in the treatment space is low, the supercritical fluid is transferred to the gaseous state due to a rapid pressure change, and the organic solvent is separated from the supercritical fluid, so that precise development treatment cannot be performed, and the substrate W may be damaged. According to the exemplary embodiment of the present invention, the pressure of the treatment space is increased by supplying only the supercritical fluid to the treatment space in the pressure increasing operation S63, and the mixed fluid is supplied to the treatment space in the subsequent treating operation S65, thereby precisely performing the developing process in the treatment space while maintaining the state in which the organic solvent is dissolved in the supercritical fluid.

When the pressure in the treatment space becomes the first set pressure, a treating operation S65 is performed. Referring to FIG. 6, in the treating operation S65, the valves 2983d and 2983e on the side of the first reservoir 2981a in the mixed fluid supply pipe 2983 are opened, and the valve 2983f on the side of the second reservoir 2981b is closed, so that the mixed fluid is supplied to the treatment space through only the first reservoir 2981a. In this case, the valve 2975d in the supercritical fluid supply pipe 2973 is closed. Thereafter, when the pressure of the mixed fluid in the mixed fluid supply pipe 2983 measured through the sensor 2983c in the mixed fluid supply pipe 2983 becomes equal to or less than a second set pressure, as illustrated in FIG. 7, the opening/closing valve 2983e on the side of the first reservoir 2981a is closed, and the opening/closing valve 2983f on the side of the second reservoir 2981b is opened to supply the mixed fluid to the treatment space only through the second reservoir 2981b. In this case, the first reservoir 2981a may receive the supercritical fluid and the organic solvent from the supercritical fluid supply pipe 2985a and the organic solvent supply pipe 2987a to produce the mixed fluid therein.

The mixed fluid supplied to the treatment space removes the photoresist layer of the target region. The region to be removed may be a photoresist layer exposed in the exposure process S40 or may be an opposite region.

When the development process is completed, the pressure reducing operation S67 is performed. Referring to FIG. 8, in the pressure reducing operation S67, the opening/closing valve 2961 of the exhaust unit 2960 is opened to exhaust the remaining supercritical fluid or mixed fluid inside the treatment space to the outside of the supercritical chamber 290 through the exhaust unit 2960.

When the pressure reducing operation S67 is completed, the unloading operation S69 is performed. In the unloading operation S69 as illustrated in FIG. 9, as the second body 2913 descends, the treatment space is opened, and the substrate W is unloaded to the outside of the supercritical chamber 290.

After the developing process S60, the hard bake process S70 is performed. In the hard bake process S70, the substrate W on which the developing process S60 is completed is heat-treated. The hard bake process S70 may include heating and cooling the substrate W. In the hard bake process S70, the substrate W is heated to remove residual mixed fluid, and the adhesion of the photoresist layer may be improved.

In the above-described exemplary embodiment of FIG. 9, it has been described that the supercritical fluid is supplied to the treatment space through the supercritical fluid supply unit 2970, but the present invention is not limited thereto, and the gas may be supplied to the treatment space and the gas may be in a supercritical state in the treatment space.

In the above-described exemplary embodiment of FIG. 1, the case where each of the plurality of reservoirs 2981 produces the mixed fluid having the same concentration or density has been described as an example, but the present invention is not limited thereto, and each reservoir 2981 may produce a mixed fluid having a different concentration or density. Accordingly, a reservoir 2981 suitable for each situation may be determined according to circumstances, such as an atmosphere of a treatment space, a development process progression degree, or a concentration or density of an internal mixed fluid, and the mixed fluid may be supplied.

In the above-described exemplary embodiment of FIG. 1, the case where the plurality of reservoirs 2981 is provided has been described as an example, but the present invention is not limited thereto, and one reservoir 2981 may be provided to the supercritical chamber 290.

In the above-described exemplary embodiment of FIG. 2, the case where the application process S20 is performed after the pretreatment process S10 has been described as an example, but the present invention is not limited thereto, and a pre-bake process may be performed to remove moisture and/or an organic materials present on the substrate W by heating the substrate W between the pretreatment process S10 and the application process S20.

In the above-described exemplary embodiment of FIG. 2, the case where the soft bake process S30, the PEB process S50, and the hard bake process S70 are performed has been described as an example, but the present invention is not limited thereto, and the application process S20, the exposure process S40, and the development process S60 may be performed while some or all of the bake processes described above are omitted.

In the above-described exemplary embodiments, the case where the supercritical supply pipe 2973 is connected to the second body 2913 to supply the supercritical fluid to the treatment space has been described as an example. The present invention is not limited thereto, and the supercritical supply pipe 2973 may be connected to the first body 2911 to supply the supercritical fluid to the treatment space.

In the above-described exemplary embodiments, the case where the development process is performed in the supercritical chamber 290 has been described as an example. However, unlike this, a cleaning process of cleaning the substrate in the supercritical chamber 290 may be performed.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A method of processing a substrate, the method comprising:
a pressure increasing operation of increasing a pressure of a treatment space to a first set pressure after the substrate is loaded into the treatment space;
after the pressure increasing operation, a treating operation of processing the substrate; and
after the treating operation, a pressure reducing operation of reducing a pressure of the treatment space,
wherein the pressure increasing operation includes increasing a pressure of the treatment space by supplying only a supercritical fluid between the supercritical fluid and the organic solvent to the treatment space, and
the treating operation includes supplying a mixed fluid obtained by dissolving the organic solvent in the supercritical fluid to the treatment space.

2. The method of claim 1, wherein the mixed fluid is produced by supplying the supercritical fluid and the organic solvent to a reservoir and mixing the supercritical fluid and the organic solvent in the reservoir.

3. The method of claim 2, wherein a plurality of reservoirs is provided, and the treating operation includes:
supplying the mixed fluid to the treatment space through only a first reservoir among the plurality of reservoirs; and
when a pressure of the mixed fluid in a supply pipe connecting the first reservoir to the treatment space is equal to or less than a second set pressure, stopping the supply of the mixed fluid from the first reservoir, and supplying the mixed fluid to the treatment space only through a second reservoir among the plurality of reservoirs.

4. The method of claim 3, wherein the first reservoir and the second reservoir supply the mixed fluid having the same concentration or density to the treatment space.

5. The method of claim 2, wherein a plurality of reservoirs is provided, and some of the plurality of reservoirs are provided to supply the mixed fluid of different concentrations or densities to the treatment space.

6. The method of claim 1, wherein the first set pressure is a process pressure.

7. The method of claim 1, wherein the first set pressure is a pressure for maintaining a state in which the organic solvent in the mixed fluid supplied to the treatment space is dissolved in the supercritical fluid.

8. The method of claim 1, wherein the substrate loaded in in the pressure increasing operation is a substrate on which an exposure process has been performed on a photoresist applied on the substrate, and
in the treating operation, the treatment of the substrate is a treatment that performs a development process on the substrate.

9. The method of claim 1, wherein the organic solvent is any one of n-butyl alcohol (nBA) and isopropyl alcohol (IPA).

10. The method of claim 1, wherein the supercritical fluid is carbon dioxide.

11. -17. (canceled)

18. A method of processing a substrate, the method comprising:
a loading operation of loading a substrate, in which an exposure process has been performed on a photoresist applied on the substrate, into a treatment space;
a pressure increasing operation of increasing a pressure of the treatment space to a first set pressure after the loading operation;
after the pressure increasing operation, a treating operation of developing the substrate; and
after the treating operation, a pressure reducing operation of reducing a pressure of the treatment space,
wherein the pressure increasing operation includes increasing a pressure of the treatment space by supplying only the supercritical fluid between the supercritical fluid and the organic solvent to the treatment space,
the treating operation includes supplying a mixed fluid obtained by dissolving the organic solvent in the supercritical fluid to the treatment space,
the organic solvent is any one of n-butyl alcohol (nBA) and isopropyl alcohol (IPA), and
the supercritical fluid is carbon dioxide.

19. The method of claim 18, wherein the mixed fluid is produced by supplying the supercritical fluid and the organic solvent to the reservoir and mixing the supercritical fluid and the organic solvent in the reservoir.

20. The method of claim 19, wherein the treating operation includes:
supplying the mixed fluid to the treatment space through only a first reservoir among the plurality of reservoirs; and
when a pressure of the mixed fluid in a supply pipe connecting the first reservoir to the treatment space is equal to or less than a second set pressure, stopping the supply of the mixed fluid from the first reservoir, and supplying the mixed fluid to the treatment space only through a second reservoir among the plurality of reservoirs.
